(19) United States
(12) Patent Application Publication
(10) Pub. No.: US 2026/0052917 A1
(43) Pub. Date: Feb. 19, 2026

(54) METHOD FOR FORMING AN INSULATING LAYER PATTERN AND SEMICONDUCTOR DEVICE

(71) Applicant: DONGJIN SEMICHEM CO., LTD., Incheon (KR)

(72) Inventors: Han Jin LEE, Hwaseong-si (KR); Jae Woo LEE, Hwaseong-si (KR); Jun Young KIM, Hwaseong-si (KR); So Jeong YEO, Hwaseong-si (KR); Hwan Soo KIM, Hwaseong-si (KR); Jang Keun SIM, Hwaseong-si (KR); Pil Soo KIM, Hwaseong-si (KR); Gyeong A LEE, Hwaseong-si (KR); Cheol Kyu BOK, Hwaseong-si (KR)

(21) Appl. No.: 19/221,782

(22) Filed: May 29, 2025

Related U.S. Application Data
(63) Continuation of application No. PCT/KR2023/095069, filed on Nov. 13, 2023.

(30) Foreign Application Priority Data
Nov. 30, 2022 (KR) 10-2022-0165255

(51) Int. Cl. H01L 21/02; H01L 21/033; H01L 21/311

(52) U.S. Cl. CPC H01L 21/02164; H01L 21/02211; H01L 21/02266; H01L 21/0228; H01L 21/02307; H01L 21/02315; H01L 21/0337; H01L 21/31116; H01L 21/31144

(57) ABSTRACT

A method for forming an insulating layer pattern includes providing a substrate including two or more different types of dielectric layer regions; selectively forming a blocking layer on the substrate to include a first region on which a blocking layer is formed and a second region on which no blocking layer is formed or the blocking layer is formed less than in the first region; selectively forming an insulating layer on the second region; and etching a portion of an upper portion of the insulating layer.

### CROSS-REFERENCE TO RELATED APPLICATIONS

This application is a Continuation of International Application No. PCT/KR2023/095069 filed Nov. 13, 2023, which claims priority from Korean Application No. 10-2022-0165255 filed Nov. 30, 2022. The aforementioned applications are incorporated herein by reference in their entireties.

### BACKGROUND

### 1. Technical Field

The present invention relates to a method for forming an insulating layer pattern and a semiconductor device.

### 2. Description of the Related Art

Semiconductor devices based on silicon materials have achieved a continuous reduction in line widths due to the rapid development of conventional top-down patterning technology and three-dimensional structuring, and methods enabling mass manufacturing of nanostructures have been dominantly employed.

Traditional top-down optical lithography involves several complex process steps, including applying photoresist (PR), conducting heat treatment, aligning pattern masks, patterning PR through photolithography, and etching the underlying thin layer according to the PR pattern. As a result, as pattern size decreases, more processing time and cost are required.

In particular, for the formation of ultrafine patterns of 10 nm or less, the introduction of new extreme ultraviolet (EUV) exposure equipment incurs significant costs of millions of dollars or more. However, technical issues such as non-uniformity in pattern line width (critical dimension, CD) and alignment (overlay), pattern loading effects, surface roughness (line edge roughness; LER, line width roughness; LWR) problem, and low pellicle efficiency are limiting the ultra-fineness and precision of pattern formation.

Therefore, a new patterning paradigm technology is needed that can selectively form precise patterns in desired areas within a multidimensional structure of 10 nm or less and can reduce process time and cost by simplifying the process steps. Area-Selective Atomic Layer Deposition (AS-ALD, also known as ASD) is being researched as a next-generation alternative patterning process, effectively utilizing the surface reaction characteristics of ALD processes to selectively form precise atomic-level thin layers in an upward (bottom-up) manner on selectively chosen areas above multi-colored patterns (i.e., patterns with various underlying materials).

Therefore, the AS-ALD process can form ultra-fine nanostructure patterns through modifying the surface properties of the substrate by selectively achieving surface modification in areas where growth is not desired, and then selectively depositing a thin layer only in the growth area due to the selective reaction of the precursor and reactor used in the subsequent ALD deposition process.

### SUMMARY

An object of the present invention is to provide a method for forming an insulating layer pattern capable of obtaining a highly uniform and high-density single-molecule selective blocking layer and insulating layer using a dry technique such as atomic layer deposition.

In addition, another object of the present invention is to provide a method for forming an insulating layer pattern that can provide advantages in terms of cost and quality by forming a selective blocking layer and an insulating layer within several minutes using the same insulating layer forming equipment without external exposure, compared to the prior dip-coating method, which requires at least several hours.

In addition, an object of the present invention is to provide a method for forming an insulating layer pattern that can create an insulating layer pattern with excellent selectivity on two or more types of dielectric layers, such as silicon nitride and silicon oxide, without an additional mask, and a precursor for forming a blocking layer used during the process.

In addition, an object of the present invention is to provide a semiconductor device having an insulating layer pattern with excellent selectivity and aspect ratio through an etching process and a repetitive process.

The above-mentioned objects and other objects will be described in detail below.

To address the above challenges, in an aspect, the present disclosure provides a method for forming an insulating layer pattern, which includes the steps of: providing a substrate including two or more different types of dielectric layer regions; selectively forming a blocking layer on the substrate to include a first region on which a blocking layer is formed and a second region on which no blocking layer is formed or relatively less amount of blocking layer is formed; selectively forming an insulating layer on the second region; and etching a portion of an upper portion of the insulating layer.

The blocking layer precursor used in the step of selectively forming the blocking layer may be a precursor represented by the following chemical formula 1 or chemical formula 2.

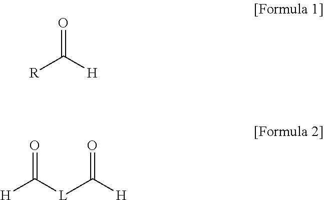

In Formula 1,

R is a substituted or unsubstituted C1-C30 alkyl group, a substituted or unsubstituted C2-C30 alkenyl group, a substituted or unsubstituted C1-C30 alkoxy group, a substituted or unsubstituted C1-C30 sulfide group, a substituted or unsubstituted C6-C50 aryl group, a substituted or unsubstituted C7-C50 aralkyl group, or a substituted or unsubstituted C2-C50 heteroaryl group. However, when the alkyl group contains 10 or more carbon atoms, one or more hydrogens of the alkyl group are substituted with halogen.

L is a substituted or unsubstituted C1-C30 alkylene group, a substituted or unsubstituted C2-C30 alkenylene group, a substituted or unsubstituted C1-C30 alkyleneoxy group, or a substituted or unsubstituted C1-C30 sulfide group, a substituted or unsubstituted C3-C50 cycloalkylene group, a substituted or unsubstituted C6-C50 arylene group, a substituted or unsubstituted C2-C50 heteroarylene group, or any combinations thereof.

In addition, the present disclosure provides a semiconductor device comprising: a substrate including two or more different types of dielectric layer regions; and a silicon oxide insulating layer formed on the substrate. The silicon oxide insulating layer includes a second region in which the silicon oxide insulating layer is selectively formed and a first region in which the silicon oxide insulating layer is not formed or formed with a relatively less amount. A thickness difference between the silicon oxide insulating layer formed on the first region and the second region is 4.5 nm or more.

The present invention can obtain a very uniform and high-density single molecule blocking layer by using a dry technique such as atomic layer deposition to form a blocking layer.

In addition, while the method of forming a blocking layer in the prior art, i.e., dip-coating, requires at least several hours, the method according to the present invention can form selective blocking and insulating layers within minutes using the same insulating layer formation equipment without external exposure. As a result, cost and quality advantages can be achieved.

In addition, an insulating layer pattern can be formed with excellent selectivity on two or more types of dielectric layers, such as silicon nitride and silicon oxide, without an additional mask.

In addition, by adding an etching process and repeating the process, a semiconductor device having an insulating layer pattern with excellent selectivity and aspect ratio can be obtained.

The above effects and other effects will be described in detail below.

### BRIEF DESCRIPTION OF THE DRAWINGS

FIG. 1 is a process flow diagram of a method for forming an insulating layer pattern according to an embodiment of the present disclosure.

FIG. 2 is a diagram showing an increase in the selectivity and aspect ratio of an insulating layer according to a repeating process of a method for forming an insulating layer pattern according to an embodiment of the present disclosure.

### DETAILED DESCRIPTION

The terms used in the present specification are used only to describe specific examples and are not intended to limit the scope of the present disclosure which will be defined only by the appended claims.

Unless otherwise defined herein, all terms including technical and scientific terms used herein have the meaning as commonly understood by those who are ordinarily skilled in the art to which the present disclosure pertains.

Unless otherwise stated herein, it will be further understood that the terms “comprise”, “comprises”, and “comprising”, when used in this specification, specify the presence of stated features, regions, integers, steps, operations, elements and/or components but do not preclude the presence or addition of one or more other features, regions, integers, steps, operations, elements, components and/or groups thereof.

Throughout the specification and claims of the disclosure, the term “aryl” refers to a functional group having a C5-50 aromatic hydrocarbon ring, and examples thereof include phenyl, benzyl, naphthyl, biphenyl, terphenyl, fluorene, phenanthrenyl, triphenylenyl, perylenyl, chrysenyl, fluoranthenyl, benzofluorenyl, benzotriphenylenyl, benzochrysenyl, anthracenyl, stilbenyl, or pyrenyl. The term “heteroaryl” refers to a C2-50 aromatic ring structure containing at least one heteroatom, and it includes a heterocyclic ring formed from pyrrolyl, pyrazinyl, pyridinyl, indolyl, isoindolyl, furyl, benzofuranyl, isobenzofuranyl, dibenzofuranyl, benzothiophenyl, dibenzothiophenyl, quinolyl group, isoquinolyl, Quinoxalinyl, carbazolyl, phenanthridinyl, acridinyl, phenanthrolinyl, thienyl, a pyridine ring, a pyrazine ring, a pyrimidine ring, a pyridazine ring, a triazine ring, an indole ring, a quinoline ring, an acridine ring, a pyrrolidine ring, a dioxane ring, a piperidine ring, a morpholine ring, a piperazine ring, a carbazole ring, a furan ring, a thiophene ring, an oxazole ring, an oxadiazole ring, a benzofuran ring, a thiazole ring, a thiadiazole ring, a benzothiophene ring, a triazole ring, an imidazole ring, a benzoimidazole ring, a pyran ring, or a dibenzofuran ring.

In chemical formulas: Arx (where x is an integer) means a substituted or unsubstituted C6-C50 aryl group, or a substituted or unsubstituted C2-C50 heteroaryl group, unless otherwise defined; Lₓ (where x is an integer) means a directly bonded and a substituted or unsubstituted C6-C50 arylene group or a substituted or unsubstituted C2-C50 heteroarylene group, unless otherwise defined; and Rx (where x is an integer), means a hydrogen, deuterium, halogen, a nitro group, a nitrile group, a substituted or unsubstituted C1-C30 alkyl group, a substituted or unsubstituted C2-C30 alkenyl group, a substituted or unsubstituted C1-C30 alkoxy group, a substituted or unsubstituted C1-C30 sulfide group, a substituted or unsubstituted C6-C50 aryl group, or a substituted or unsubstituted C2-C50 heteroaryl group, unless otherwise defined.

Throughout the present specification and claims, the term “substituted or unsubstituted” means that a portion is substituted or unsubstituted by at least one selected from the group consisting of deuterium, halogen, amino group, cyano group, nitrile group, nitro group, nitroso group, sulfamoyl group, isothiocyanate group, thiocyanate group, carboxyl group, carbonyl group, C1-C30 alkyl group, C1-C30 alkylsulfinyl group, C1-C30 alkylsulfonyl group, C1-C30 alkylsulfanyl group, C1-C12 fluoroalkyl group, C2-C30 alkenyl group, C1-C30 alkoxy group, C1-C12 N-alkylamino group, C2-C20 N, N-dialkylamino group, substituted or unsubstituted C1-C30 sulfide group, C1-C6 N-alkylsulfamoyl group, C2-C12 N, N-dialkylsulfamoyl group, CO-C30silyl group, C3-C20 cycloalkyl group, C3-C20 heterocycloalkyl group, C6-C50 aryl group, C3-C50 heteroaryl group, etc. However, the present disclosure is not particularly limited thereto. In addition, the same symbols throughout the present specification may have the same meaning unless otherwise specified.

All or some embodiments described herein may be selectively combined and configured so that the embodiments may be modified in various ways unless the context clearly indicates otherwise. Hereinafter, embodiments of the present disclosure and the effects thereof will be described in detail below.

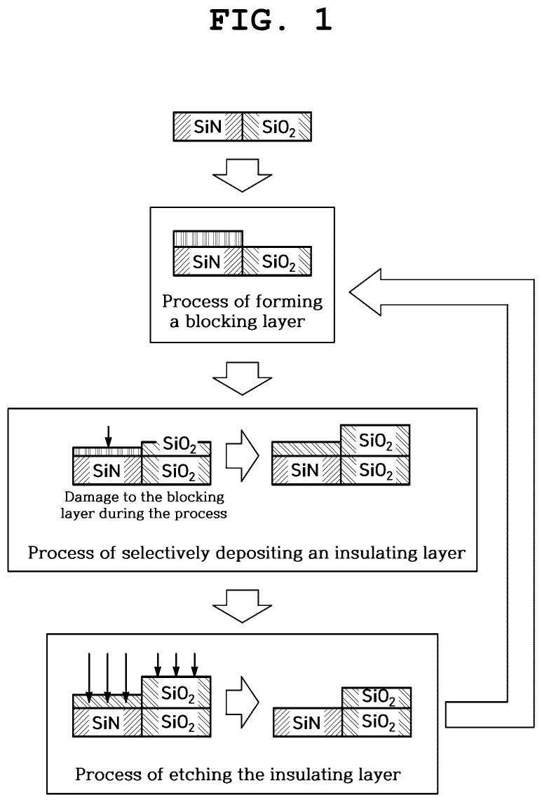

As illustrated in FIG. 1, a method for forming an insulating layer pattern according to an embodiment of the present disclosure includes the steps of: providing a substrate including two or more different types of dielectric layer regions; selectively forming a blocking layer on the substrate so as to include a first region on which a blocking layer is formed and a second region on which no blocking layer or a less blocking layer (e.g., substantially thinner than in the first region) is formed; selectively forming an insulating layer on the second region; and etching a portion of an upper portion of the insulating layer.

The above insulating layer may specifically be a silicon oxide insulating layer.

After the step of forming the blocking layer, a difference in water contact angle between the first area and the second area may be within the range of 7 to 50 degrees, and specifically may be within the range of 7 to 40 degrees. Within the above range, an insulating layer can be formed with high selectivity.

After selectively forming the blocking layer, the method may further include forming a silicon oxide insulating layer on the second region where the blocking layer is not formed or relatively less formed.

As used herein, the term “selective” includes both cases where only one element is wholly selected and cases where one element is selected relatively more than the other element.

The surfaces of two or more different types of dielectric layer regions of the substrate may include an amine-terminated silicon region and a hydroxy-terminated silicon region. In a specific embodiment of the present disclosure, an insulating layer pattern can be formed by selectively forming a blocking layer by dividing the amine-terminated silicon region and a hydroxy-terminated silicon region and then selectively forming an insulating layer. The amine-terminated silicon region may specifically include a silicon nitride layer, and the hydroxy-terminated silicon region may specifically include a silicon oxide layer.

Meanwhile, in order to further increase selectivity, the step of pre-treating the substrate including the dielectric layer region may be further included before selectively forming the blocking layer.

When pretreatment is performed, the difference in water contact angle between the first and second regions increases to a range of 22 to 40 degrees, resulting in a greater difference in surface reactivity between the precursor used to form the blocking layer and the two regions. The difference in surface reactivity allows the blocking layer to be more selectively formed in the first region and the insulating layer to be selectively formed in the second region.

The step of pretreating the substrate may include, but not limited to, the following methods. For example, a method of dipping the substrate in an HF aqueous solution or thermal annealing in an HF gas atmosphere may be used. As another example, thermal annealing or plasma treating of the substrate in a gas atmosphere of Ne, He, ammonia, hydrazine, or mixtures thereof may be performed.

The pretreatment performed by the vapor phase process described above may use deposition equipment such as ALD or CVD, and the pretreatment may be performed within a substrate temperature range of 0 to 800° C.

In the step of selectively forming the blocking layer, various methods using gas-phase reaction, such as CVD (Chemical Vapor Deposition) and ALD (Atomic Layer Deposition), may be used. Specifically, the step of selectively forming a blocking layer includes the first step of supplying a precursor for forming a blocking layer and the second step of purging, and the steps may be repeated two or more times. The purging uses an inert gas, and the inert gas may be one or more of nitrogen (N₂), argon, neon, or helium.

The precursor for forming a blocking layer used in the step of selectively forming a blocking layer according to one embodiment of the present disclosure can be represented by chemical formula 1 or chemical formula 2 below.

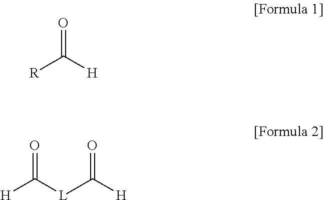

In Formula 1,

R is a substituted or unsubstituted C1-C30 alkyl group, a substituted or unsubstituted C2-C30 alkenyl group, a substituted or unsubstituted C1-C30 alkoxy group, a substituted or unsubstituted C1-C30 sulfide group, a substituted or unsubstituted C6-C50 aryl group, a substituted or unsubstituted C7-C50 aralkyl group, or a substituted or unsubstituted C2-C50 heteroaryl group. When the alkyl group contains 10 or more carbon atoms, one or more hydrogens of the alkyl group are substituted with halogen.

L is a substituted or unsubstituted C1-C30 alkylene group, a substituted or unsubstituted C2-C30 alkenylene group, a substituted or unsubstituted C1-C30 alkyleneoxy group, or a substituted or unsubstituted C1-C30 sulfide group, a substituted or unsubstituted C3-C50 cycloalkylene group, a substituted or unsubstituted C6-C50 arylene group, a substituted or unsubstituted C2-C50 heteroarylene group, or any combinations thereof.

When substituted, the substituent may be at least one selected from the group consisting of deuterium, halogen, amino group, cyano group, nitrile group, nitro group, nitroso group, sulfamoyl group, isothiocyanate group, thiocyanate group, carboxyl group, C1-C30 alkyl group, C1-C30 alkylsulfinyl group, C1-C30 alkylsulfonyl group, C1-C30 alkylsulfanyl group, C1-C12 fluoroalkyl group, C2-C30 alkenyl group, C1-C30 alkoxy group, C1-C12 N-alkylamino group, C2-C20 N, N-dialkylamino group, substituted or unsubstituted C1-C30 sulfide group, C1-C6 N-alkylsulfamoyl group, C2-C12 N, N-dialkylsulfamoyl group, CO-C30silyl group, C3-C20 cycloalkyl group, C3-C20 heterocycloalkyl group, C6-C50 aryl group, and C2-C50 heteroaryl group.

Specifically, in R, one or more hydrogens bonded to carbon may be substituted with halogen. Specifically, the halogen may be fluorine. Specifically, R may be a C1-C20 alkyl group substituted with one or more fluorines or a C6-C50 aryl group substituted with one or more fluorines.

The step of forming a silicon oxide insulating layer on the second region where the blocking layer is not formed or relatively less formed, is performed by using sputtering, CVD (Chemical Vapor Deposition), or ALD (Atomic Layer Deposition) method, etc.

Specifically, in the step of forming the insulating layer, as an oxygen source, one or more selected from the group consisting of oxygen, hydrogen peroxide, ozone, nitrogen monoxide, water plasma, oxygen plasma, residual water in the chamber, and oxygen may be used. As a nitrogen source, one or more selected from the group consisting of ammonia, hydrazine, alkylhydrazine, dialkylhydrazine, nitrogen plasma, plasma of a mixed gas of nitrogen and hydrogen, ammonia plasma, plasma of a mixed gas of ammonia and hydrogen, and mixtures thereof may be used.

Specifically, taking a silicon oxide insulating layer as an example, the insulating layer can be formed by repeating the four-step unit process of supplying primary raw material (Si precursor)—purging—supplying secondary raw material (reactant)—purging, as in a typical ALD process. In addition, the insulating layer forming process may repeat the cycle until a layer having a predetermined thickness is achieved.

Additionally, when repeating the insulating layer forming process cycle, a step of selectively forming the above-described blocking layer may be added in the middle of the cycle to increase selectivity.

When using the Si precursor as the primary raw material, examples of the Si precursor may be silanes, and the silanes may be specifically selected from SiH₄, Diisoprophylamino Silane (DIPAS), Bis-Diethylamino Silane (BDEAS), Tris(dimethylamino) silane (TDMAS), Bis(t-butylamino) silane (BTBAS), or any combinations thereof. The reactant used as the secondary raw material may be the previously exemplified oxygen source or nitrogen source.

During the insulating layer forming process, the purging may be performed by using an inert gas, and the inert gas used in the step of selectively forming a blocking layer may be used.

During the above insulating layer formation process, the blocking layer may be removed by an oxidizing reactant or the like during the process, and all or part of the blocking layer may remain.

As described above, after selectively forming an insulating layer on a second region where a blocking layer is not formed or is relatively less formed, an upper portion of the insulating layer is etched.

During the process of forming an insulating layer, the blocking layer may be damaged by an oxidizing reactant, which may result in some insulating layer deposition in the first region even with the blocking layer formed. Although it is possible to etch only the insulating layer formed in the first region using a mask, there are disadvantages such as having to manufacture an additional mask and align the mask to the pattern. Thus, an etching process is performed to remove both the insulating layer formed in the first region and an upper portion of the insulating layer formed in the second region. At this time, any blocking layer that may remain in the first region may also be etched.

There are various etching methods that can be used, such as dry etching and wet etching. Specifically, dry etching can be gas phase etching using reactive gases such as NF₃ and HF, and plasma etching using plasma such as hydrogen plasma and argon plasma. Wet etching can be performed using reactive solutions such as hydrofluoric acid and phosphoric acid. In the case of wet etching, a subsequent washing process using deionized water can be performed to remove any remaining etching agent on the substrate surface.

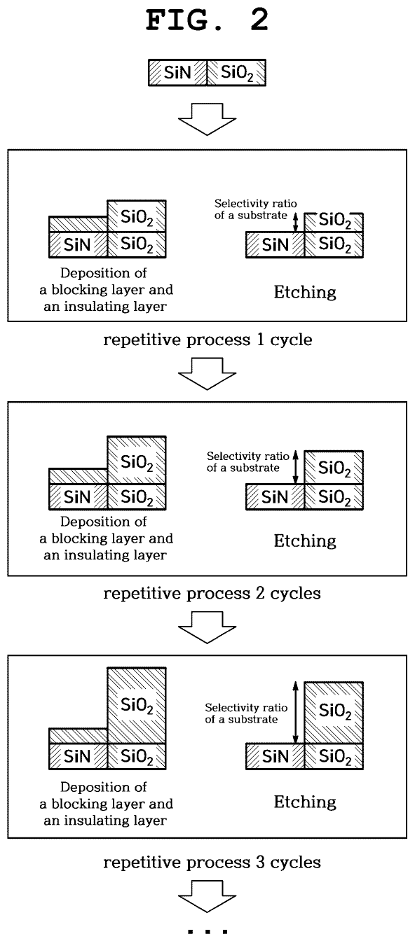

Meanwhile, as illustrated in FIG. 2, the step of selectively forming the blocking layer, the step of selectively forming the insulating layer, and the step of etching may be repeated one or more times. The number of repetitions is not limited, and can be repeated until the required thickness of the selective insulating layer pattern of the semiconductor device is reached. As can be seen in the experimental examples described below, by repeating the process, the selectivity can be increased, and the aspect ratio (e.g., height versus base dimension) of the insulating layer pattern can be significantly increased.

As an embodiment of the present disclosure, a semiconductor device is provided. The semiconductor device according to an embodiment of the present disclosure includes a substrate including two or more different types of dielectric layer regions, and a silicon oxide insulating layer formed on the substrate. The silicon oxide insulating layer includes a second region in which the silicon oxide insulating layer is selectively formed and a first region in which no or substantially less (e.g., thinner) silicon oxide insulating layer is formed. The thickness difference between the silicon oxide insulating layer formed on the first region and the second region is 4.5 nm or more, specifically 8.0 nm or more.

Here, the description for the same configuration and structure is omitted to avoid obscuring the disclosure. In a semiconductor device according to an embodiment of the present disclosure, a silicon oxide insulating layer is selectively formed on two or more types of dielectric layer regions, so that the thickness difference between the insulating layers is 0.8 nm or more, and a highly selective insulating layer pattern can be obtained without using an additional mask pattern. In particular, by repeating the process multiple times, the thickness difference of the insulating layer can be increased to 8.0 nm or more.

Hereinafter, the present disclosure will be described in more detail with specific examples. The following examples are merely illustrative of the present disclosure and the scope of the present disclosure is not limited to the following examples.

### <Experimental Example 1> Method of Forming a Blocking Layer

In this experimental example, a traveling method of atomic layer deposition was introduced to form a blocking layer. The precursor for forming the blocking layer was used in a canister, and the canister temperature was maintained at a constant temperature between −20 and 100° C. to ensure stable supply.

The unit cycle for the ALD process included (i) precursor injection for blocking layer formation and then (ii) purge. High purity nitrogen was used as purge gas with a flow rate of 300 sccm. The cycle was repeated 1 to 100 times as needed. As the substrates, Si₃N₄ and SiO₂ wafers were used with HF aqueous solution treatment or without treatment, respectively. The temperature of the substrate was tested by adjusting it between 25 and 300° C. The results of the blocking layer formation were confirmed using a water contact angle analyzer, and the results are shown in Table 1 below.

TABLE 1

| | | | | | Pretreated with HF | | |
|---|---|---|---|---|---|---|---|
| | | No pretreatment | | | aqueous solution | | |
| | Pretreated or not | SiO2 | SiN | | SiO2 | SiN | |
| | Precursor for | area | area | contact | area | area | contact |
| | forming a | contact | contact | angle | contact | contact | angle |
| Classification | blocking layer | angle | angle | difference | angle | angle | difference |
| Comparative | Unapplied | 25.0 | 28.1 | 3.1 | 13.4 | 27.8 | 14.4 |
| Example 1 | | | | | | | |
| Comparative | undecanal | 39.0 | 45.6 | 6.6 | 31.4 | 52.8 | 21.4 |
| Example 2 | | | | | | | |
| Example 1 | 11- | 39.7 | 48.5 | 8.8 | 29.6 | 54.9 | 25.3 |
| | fluoroundecanal | | | | | | |
| Example 2 | 4- | 39.0 | 49.2 | 10.2 | 27.1 | 56.0 | 28.9 |
| | (trifluoromethyl)benzaldehyde | | | | | | |
| Example 3 | 2,3,4,5,6- | 40.7 | 49.3 | 8.6 | 32.6 | 60.6 | 28.0 |
| | pentafluorobenzaldehyde | | | | | | |
| Example 4 | 7H- | 49.1 | 60.1 | 11.0 | 44.7 | 77.3 | 32.6 |
| | dodecafluoroheptanal | | | | | | |
| Example 5 | Isophthalaldehyde | 43.4 | 52.7 | 9.3 | 28.5 | 56.7 | 28.2 |
| Example 6 | 1,8- | 38.5 | 50.2 | 11.7 | 31.4 | 66.0 | 34.6 |
| | Octanedialdehyde | | | | | | |
| Example 7 | 2,2,3,3,4,4,5, | 49.8 | 63.6 | 13.8 | 42.7 | 79.7 | 37.0 |
| | 5- | | | | | | |
| | Octafluorohexanedialdehyde | | | | | | |

As shown in Table 1, when a blocking layer was formed as in Examples 1 to 7, the contact angle difference was more than 8 degrees, specifically in the range of 8.6 to 13.8 degrees. It was demonstrated that the contact angle difference was significantly larger for Examples 1-7 compared to the contact angle difference of 3.1 degrees for Comparative Example 1, in which no blocking layer was formed. In addition, in the case of Comparative Example 2, which had one aldehyde group, 10 or more carbon atoms in the alkyl group, and no fluorine substituent, the contact angle difference was relatively small at 6.6 degrees.

In addition, it was demonstrated that by pretreating the substrate, the contact angle difference was able to be significantly increased to more than 22 degrees, specifically in the range of 22 to 40 degrees, compared to the case without pretreatment.

### <Experimental Example 2> Formation of Silicon Oxide Insulating Layer

In this experimental example, traveling-type atomic layer deposition was introduced, and SiO₂ layer formation was evaluated using DIPAS (Di-isopropylamino Silane) as a Si precursor and ozone (O₃) as a reactant. The Si precursor was used in a canister, and the process was carried out without any additional heating.

The unit cycle for the ALD process included Si precursor injection—purge—reactants injection—purge. High purity nitrogen was used as purge gas. The cycle was repeated 1 to 200 times until a desired thickness was reached, and a blocking layer deposition process could be added between these processes. As a substrate, the Si₃N₄ and SiO₂ wafers with the blocking layers of Experimental Example 1 were used. The temperature of the substrate was tested by adjusting it between 25 and 300° C. The thickness of the thin layer was measured using an ellipsometer and the results are shown in Table 2.

TABLE 2

| | | | | | Pretreated with HF | | |
|---|---|---|---|---|---|---|---|
| | | No pretreatment | | | aqueous solution | | |
| | | SiO2 | SiN | | SiO2 | SiN | |
| | Pretreated | area | area | | area | area | |
| | or not | insulation | insulation | | insulation | insulation | |
| | forming a | layer | layer | | layer | layer | |
| | blocking | thickness | thickness | Thickness | thickness | thickness | Thickness |
| Classification | layer | (nm) | (nm) | difference | (nm) | (nm) | difference |
| Comparative | Unapplied | 8.0 | 7.7 | 0.3 | 8.3 | 7.1 | 1.2 |
| Example 3 | | | | | | | |
| Comparative | undecanal | 7.8 | 7.1 | 0.7 | 7.7 | 5.6 | 2.1 |
| Example 4 | | | | | | | |
| Example 8 | 11- | 7.6 | 6.8 | 0.8 | 8.1 | 5.3 | 2.8 |
| | fluoroundecanal | | | | | | |
| Example 9 | 4- | 7.7 | 6.7 | 1.0 | 8.0 | 4.4 | 3.6 |
| | (trifluoromethyl)benzaldehyde | | | | | | |
| Example 10 | 2,3,4,5,6- | 7.1 | 6.3 | 0.8 | 8.1 | 5.1 | 3.0 |
| | pentafluorobenzaldehyde | | | | | | |
| Example 11 | 7H- | 7.5 | 6.4 | 1.1 | 8.1 | 3.7 | 4.4 |
| | dodecafluoroheptanal | | | | | | |
| Example 12 | Isophthalaldehyde | 7.4 | 6.5 | 0.9 | 8.5 | 5.3 | 3.2 |
| Example 13 | 1,8- | 7.7 | 6.4 | 1.3 | 8.2 | 3.7 | 4.5 |
| | Octanedialdehyde | | | | | | |
| Example 14 | 2,2,3,3,4,4,5,5- | 7.6 | 6.1 | 1.5 | 8.4 | 3.4 | 5.0 |
| | Octafluorohexanedialdehyde | | | | | | |

As shown in Table 2, when a blocking layer was formed as in Examples 8 to 14, the difference in the thickness of the insulating layer was 0.8 nm or more, specifically in the range of 0.8 nm to 1.5 nm. It was demonstrated that the difference in insulating layer thickness was significantly larger for Examples 8-14 compared to the 0.3 nm difference in insulating layer thickness in Comparative Example 3, in which no blocking layer was formed. In addition, in the case of Comparative Example 4, which has one aldehyde group, 10 or more carbon atoms in the alkyl group, and no fluorine substituent, the difference in the thickness of the insulating layer was relatively small at 0.7 nm.

In addition, it was demonstrated that by pre-treating the substrate, the insulating layer thickness difference was able to be significantly increased to 2.2 nm or more, specifically in the range of 2.8 nm to 5.0 nm, compared to the case without pre-treatment.

### <Experimental Example 3>Method for Selective Deposition of Silicon Insulating Layer Using Blocking Layer Formation-Insulating Layer Deposition-Etching Process

The same method for forming a blocking layer as in Experimental Example 1 was used, but the substrate was pretreated with an HF aqueous solution and then the blocking layer was selectively formed. Subsequently, the same method of forming a silicon oxide insulating layer as in Experimental Example 2 was used, but the insulating layer formation process cycle was reduced by half to form an insulating layer.

Subsequently, an etching process was performed using low-concentration hydrofluoric acid. During the low-concentration hydrofluoric acid etching, a wet etching process using a hydrofluoric acid solution was performed, and after the etching, deionized water (DI water) was used to remove the hydrofluoric acid solution and wash the surface.

The concentration of the hydrofluoric acid solution was 0.1 Vol %. Etching was performed for 7 seconds, and surface washing using deionized water was performed for 3 seconds. Etching was performed until the SiO₂ insulating layer deposited in the area where the blocking layer was formed was completely removed. The presence or absence of the insulating layer was confirmed by measuring the thickness of the SiO₂ insulating layer using an ellipsometer.

The blocking layer deposition-insulating layer deposition-etching process was performed in the above three processes in order, and the process of completing the three processes sequentially was considered as one cycle. In the experimental example, the cycle was repeated a total of 6 times. As a result, the thickness of the thin layer was measured using an ellipsometer and is shown in Table 3.

TABLE 3

| | | | SiO2 thickness |
|---|---|---|---|
| Cycle No. | Process steps | Lower substrate | (nm) |
| 1 Cycle | Insulating layer | SiO₂ | 3.2 |
| | deposition | SiN | 2.4 |
| | | SiO2 thickness | 0.8 |
| | | difference | |
| | Low concentration | SiO₂ | 1.5 |
| | hydrofluoric acid | SiN | 0 |
| | etching after | SiO2 thickness | 1.5 |
| | insulating layer | difference | |
| | deposition | | |
| 2 Cycles | Insulating layer | SiO₂ | 4.9 |
| | deposition | SiN | 2.4 |
| | | SiO2 thickness | 2.5 |
| | | difference | |
| | Low concentration | SiO₂ | 3.1 |
| | hydrofluoric acid | SiN | 0 |
| | etching after | SiO2 thickness | 3.1 |
| | insulating layer | difference | |
| | deposition | | |
| 3 cycles | Insulating layer | SiO₂ | 7.0 |
| | deposition | SiN | 2.4 |
| | | SiO2 thickness | 4.6 |
| | | difference | |
| | Low concentration | SiO₂ | 4.7 |
| | hydrofluoric acid | SiN | 0 |
| | etching after | SiO2 thickness | 4.7 |
| | insulating layer | difference | |
| | deposition | | |
| 4 cycles | Insulating layer | SiO₂ | 8.4 |
| | deposition | SiN | 2.4 |
| | | SiO2 thickness | 6.0 |
| | | difference | |
| | Low concentration | SiO₂ | 5.7 |
| | hydrofluoric acid | SiN | 0 |
| | etching after | SiO2 thickness | 5.7 |
| | insulating layer | difference | |
| | deposition | | |
| 5 cycles | Insulating layer | SiO₂ | 9.2 |
| | deposition | SiN | 2.1 |
| | | SiO2 thickness | 7.1 |
| | | difference | |
| | Low concentration | SiO₂ | 6.7 |
| | hydrofluoric acid | SiN | 0 |
| | etching after | SiO2 thickness | 6.7 |
| | insulating layer | difference | |
| | deposition | | |
| 6 cycles | Insulating layer | SiO₂ | 10.1 |
| | deposition | SiN | 2.4 |
| | | SiO2 thickness | 7.7 |
| | | difference | |
| | Low concentration | SiO₂ | 8.0 |
| | hydrofluoric acid | SiN | 0 |
| | etching after | SiO2 thickness | 8.0 |
| | insulating layer | difference | |
| | deposition | | |

As shown in Table 3, when a blocking layer was formed and an etching process was additionally performed, it was confirmed that the difference in the thickness of the insulating layer increased from 1.5 nm to 3.1 nm, 4.7 nm, 5.7 nm, 6.7 nm, and 8.0 nm as the process was repeated, enabling the implementation of an ultra-fine pattern with a high aspect ratio.

What is claimed is:

1. A method for forming an insulating layer pattern, comprising:
providing a substrate including two or more different types of dielectric layer regions; and
selectively forming a blocking layer on the substrate to include a first region on which a blocking layer is formed and a second region on which no blocking layer is formed or the blocking layer is formed in a substantially less thickness than in the first region;
selectively forming an insulating layer on the second region; and
etching a portion of an upper portion of the insulating layer.

2. The method of claim 1, wherein the insulating layer is a silicon oxide insulating layer.

3. The method of claim 1, wherein a difference in water contact angle between the first region and the second region is within a range of 7 to 50 degrees after said step of selectively forming the blocking layer.

4. The method of claim 1, further comprising: pre-treating the substrate before selectively forming the blocking layer.

5. The method of claim 4, wherein a difference in water contact angle between the first region and the second region is within a range of 22 to 40 degrees.

6. The method of claim 4, wherein said step of pre-treating the substrate comprises dipping in an HF solution or thermal annealing in an HF gas atmosphere.

7. The method of claim 4, wherein said step of pre-treating the substrate comprises thermal annealing or plasma treating of the substrate in a gas atmosphere of N₂, H₂, ammonia, hydrazine, or any mixtures thereof.

8. The method of claim 1, wherein surfaces of the dielectric layer regions of the substrate include an amine-terminated silicon region and a hydroxy-terminated silicon region.

9. The method of claim 1, wherein the dielectric layer regions of the substrate include a silicon nitride layer region and a silicon oxide layer region.

10. The method of claim 1, wherein said step of forming a silicon oxide insulating layer is performed by using sputtering, Chemical Vapor Deposition (CVD), or Atomic Layer Deposition (ALD).

11. The method of claim 2, wherein the precursor used to form the silicon oxide insulating layer is selected from the group consisting of SiH₄, Diisoprophylamino Silane (DIPAS), Bis-Diethylamino Silane (BDEAS), Tris(dimethylamino)silane (TDMAS), Bis(t-butylamino)silane (BTBAS), and any combinations thereof.

12. The method of claim 1, wherein in said step of etching, the insulating layer formed in the first region is also etched.

13. The method of claim 12, wherein in said step of etching, the blocking layer formed in the first region is also etched.

14. The method of claim 1, wherein said steps of selectively forming the blocking layer; selectively forming the insulating layer; and etching are repeated one or more times.

15. The method of claim 1, wherein a precursor for forming the blocking layer used in said step of selectively forming the blocking layer is represented by the following chemical formula 1 or chemical formula 2: 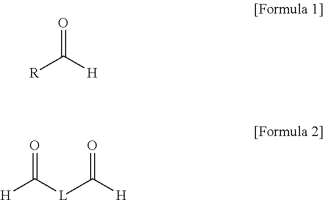
wherein, in Formula 1,
R is a substituted or unsubstituted C1-C30 alkyl group, a substituted or unsubstituted C2-C30 alkenyl group, a substituted or unsubstituted C1-C30 alkoxy group, a substituted or unsubstituted C1-C30 sulfide group, a substituted or unsubstituted C6-C50 aryl group, a substituted or unsubstituted C7-C50 aralkyl group, or a substituted or unsubstituted C2-C50 heteroaryl group, wherein, when the alkyl group contains 10 or more carbon atoms, one or more hydrogens of the alkyl group are substituted with halogen, and
L is a substituted or unsubstituted C1-C30 alkylene group, a substituted or unsubstituted C2-C30 alkenylene group, a substituted or unsubstituted C1-C30 alkyleneoxy group, or a substituted or unsubstituted C1-C30 sulfide group, a substituted or unsubstituted C3-C50 cycloalkylene group, a substituted or unsubstituted C6-C50 arylene group, a substituted or unsubstituted C2-C50 heteroarylene group, or any combinations thereof.

16. The method of claim 15, wherein the substituent for the above R or L is at least one selected from the group consisting of deuterium, halogen, amino group, cyano group, nitrile group, nitro group, nitroso group, sulfamoyl group, isothiocyanate group, thiocyanate group, carboxyl group, C1-C30 alkyl group, C1-C30 alkylsulfinyl group, C1-C30 alkylsulfonyl group, C1-C30 alkylsulfanyl group, C1-C12 fluoroalkyl group, C2-C30 alkenyl group, C1-C30 alkoxy group, C1-C12 N-alkylamino group, C2-C20 N, N-dialkylamino group, substituted or unsubstituted C1-C30 sulfide group, C1-C6 N-alkylsulfamoyl group, C2-C12 N, N-dialkylsulfamoyl group, C3-C30 silyl group, C3-C20 cycloalkyl group, C3-C20 heterocycloalkyl group, C6-C50 aryl group, and C2-C50 heteroaryl group.

17. A semiconductor device comprising:
a substrate including two or more different types of dielectric layer regions; and
a silicon oxide insulating layer formed on the substrate, wherein the silicon oxide insulating layer includes a first region and a second region in which the silicon oxide insulating layer is selectively formed such that, in the second region, the silicon oxide insulating layer is formed, and in the first region, no silicon oxide insulating layer is formed or the silicon oxide insulating layer is formed with a substantially less thickness than in the second region,
wherein a thickness difference between the silicon oxide insulating layer formed on the first region and the second region is 4.5 nm or more.

18. The semiconductor device of claim 17, wherein the thickness difference between the silicon oxide insulating layer formed on the first region and the second region is 8.0 nm or more.
